(19) United States
(12) Patent Application Publication
(10) Pub. No.: US 2021/0068314 A1
(43) Pub. Date: Mar. 4, 2021

(54) FLEXIBLE DISPLAY DEVICE AND METHOD FOR IMPROVING STABILITY OF FLEXIBLE DISPLAY DEVICE

(71) Applicant: WUHAN CHINA STAR OPTOELECTRONICS SEMICONDUCTOR DISPLAY TECHNOLOGY CO., LTD., Wuhan, Hubei (CN)

(72) Inventor: Xia CHEN, Wuhan, Hubei (CN)

(21) Appl. No.: 16/638,766

(22) PCT Filed: Nov. 19, 2019
(86) PCT No.: PCT/CN2019/119506

§ 371 Date: Feb. 13, 2020

(30) Foreign Application Priority Data
Sep. 3, 2019 (CN) 201910825543.X

(51) Int. Cl. H05K 7/20; G06F 1/16

(52) U.S. Cl. CPC H05K 7/20963; G06F 1/1616; G06F 1/1652

(57) ABSTRACT

A flexible display device is provided. The flexible display device includes a display module, a heat plate, a heat collecting component, and a heat conducting tube connecting the heat plate to the heat collecting component. The heat plate transmits heat to a bending portion of the display module when the display module is in an expanded state. By collecting the heat during the operation, the collected heat is applied to the warped bending portion when the flexible display device is flattened, so that the warped bending portion is restored to be flat, thereby improving the product appearance and product stability.

### CROSS REFERENCE TO RELATED APPLICATIONS

This application claims priority to Chinese Application No. 201910825543.X, filed on Sep. 3, 2019, the title of which is “FLEXIBLE DISPLAY DEVICE AND METHOD FOR IMPROVING STABILITY OF FLEXIBLE DISPLAY DEVICE”, the entire disclosure of which is incorporated herein by reference.

### FIELD OF INVENTION

The present disclosure relates to the technical field of display, and in particular, relates to a flexible display device and a method for improving stability of a flexible display device.

### BACKGROUND OF INVENTION

With the release of flexible and bendable products on the market, the pace of mass production of flexible and bendable products is getting faster and faster. Major panel manufacturers are heavily investing in developing flexible bendable products. In order to achieve product goals of dynamically bendability, new designs, new materials, and new manufacturing processes need to be introduced to improve the performance of flexible and bendable products. In the flexible display devices, the module film material is mainly a polymer film material. After a large number of bending times (such as more than 200,000 times) or a small bending radius (less than 3 mm), material stress relaxation and bending fatigue are likely to occur, which cause surface warping after the display is flattened, thereby affecting the appearance and flatness of the produce.

### SUMMARY OF INVENTION

### Technical Problem

An object of the present disclosure is to provide a flexible display device and a method for improving stability of a flexible display device to solve the technical problem in the existing flexible display devices as follows. Since the film material in the display module is mainly a polymer thin film material, in the case of excessive bending times or small bending curvature, stress relaxation and bending fatigue of the material are liable to occur. After the display device is deployed, the surface will warp, which will affect the appearance and flatness of the product.

### Technical Solution

To achieve the above object, the technical solution provided by the present disclosure is as follows:

The present disclosure provides a flexible display device, and the flexible display device includes a display module, a heat plate, a heat collecting component, and a heat conducting tube, wherein the display module includes a bending area, wherein a bending line is defined in the bending area, and the display module is bent along the bending line; the heat plate is disposed on a side of the display module away from a light emitting surface; the heat collecting component is disposed on the side of the display module away from the light emitting surface; the heat conducting tube connects the heat plate with the heat collecting component; the heat plate corresponds to the bending area, and the heat plate transmits heat to a portion of the display module located in the bending area in an expanded state of the display module; an orthographic projection of the heat plate on the display module is located in the bending area, and the heat plate is attached to a surface of the display module away from the light emitting surface.

In at least one embodiment of the present disclosure, a center line of the heat plate and the bending line of the bending area coincide in a thickness direction of the display module.

In at least one embodiment of the present disclosure, the heat conducting tube is disposed on the side of the display module away from the light emitting surface.

In at least one embodiment of the present disclosure, the display module includes a driving chip, a battery, and a motherboard; the heat collecting component collects heat generated in the driving chip, the battery, and the motherboard.

In at least one embodiment of the present disclosure, the heat conducting tube is a copper tube or a carbon fiber tube.

The present disclosure further provides a flexible display device, and the flexible display device includes a display module, a heat plate, a heat collecting component, and a heat conducting tube; wherein the display module includes a bending area, wherein a bending line is defined in the bending area, and the display module is bent along the bending line; the heat plate is disposed on a side of the display module away from a light emitting surface; the heat collecting component is disposed on the side of the display module away from the light emitting surface; the heat conducts tube connecting the heat plate with the heat collecting component; wherein the heat plate corresponds to the bending area, and the heat plate transmits heat to a portion of the display module located in the bending area in an expanded state of the display module.

In at least one embodiment of the present disclosure, an orthographic projection of the heat plate on the display module is located in the bending area.

In at least one embodiment of the present disclosure, a center line of the heat plate and the bending line of the bending area coincide in a thickness direction of the display module.

In at least one embodiment of the present disclosure, the heat plate is attached to a surface of the display module away from the light emitting surface.

In at least one embodiment of the present disclosure, the heat conducting tube is disposed on the side of the display module away from the light emitting surface.

In at least one embodiment of the present disclosure, the display module includes a driving chip, a battery, and a motherboard; the heat collecting component collects heat generated in the driving chip, the battery, and the motherboard.

In at least one embodiment of the present disclosure, the heat conducting tube is a copper tube or a carbon fiber tube.

The present disclosure further provides a method for improving stability of a flexible display device, and the method comprises steps of:

a step S10, providing a display module, wherein a bending area and a bending line are defined on the display module, and the display module is able to bent along the bending line;

a step S20, disposing a heat plate, a heat collecting component, and a heat conducting tube away from a light emitting surface, wherein the heat conducting tube connects the heat collecting component with the heat plate, and the heat plate corresponds to the bending area;

a step S30, collecting heat generated by internal components of the display module through the heat collecting component when the display module works; and

a step S40, transferring the heat collected from the heat collecting component to the heat plate after unfolding the display module, wherein the heat plate transmits the heat to the display module, and heats a portion of the display module located in the bending area, so that the bending area of the display module is restored to be flat.

In at least one embodiment of the present disclosure, in the step S30, the heat collecting component collects the heat generated by a driving chip, a battery, and a motherboard of the display module.

In at least one embodiment of the present disclosure, in the step S40, the heating temperature of the portion of the display module located in the bending area does not exceed 50° C.

In at least one embodiment of the present disclosure, the heat conducting tube is a copper tube or a carbon fiber tube.

### Beneficial Effects

The heat plate and the heat collecting component are arranged on the back surface of the display module to collect heat generated during the operation of the display device. When the flexible display device is flattened, the collected heat is applied to the bending portion with warpage to accelerate the molecular movement, so that the warped bending portion is restored to be flat, thereby improving the appearance of the produce and the stability of the product.

### DESCRIPTION OF DRAWINGS

In order to more clearly illustrate technical solutions in embodiments of the present disclosure, the drawings used in the description of the embodiments will be briefly introduced below. Obviously, the drawings in the following description are only some embodiments of the present disclosure, and those skilled in the art can obtain other drawings according to these drawings without any creative effort.

FIG. 1 is a cross-section view of a flexible display device according to an embodiment of the present disclosure.

FIG. 2 is a schematic structural view of a display module according to an embodiment of the present disclosure.

FIG. 3 is a flow chart of method for improving stability of a flexible display device according to an embodiment of the present disclosure.

### DETAILED DESCRIPTION OF PREFERRED EMBODIMENTS

Structural and technical means adopted by the present disclosure to achieve the above and other objects can be best understood by referring to the following detailed description of the preferred embodiments and the accompanying drawings. Furthermore, directional terms described by the present disclosure, such as upper, lower, front, back, left, right, inner, outer, side, longitudinal/vertical, transverse/horizontal, etc., are only directions by referring to the accompanying drawings, and thus the used directional terms are used to describe and understand the present disclosure, but the present disclosure is not limited thereto.

For existing flexible display devices, since the film material in the display module is mainly a polymer thin film material, in the case of excessive bending times or small bending curvature, stress relaxation and bending fatigue of the material are liable to occur. After the display device is deployed, the surface will warp, which will affect the appearance and flatness of the product. This embodiment of the present disclosure is able to solve this defect.

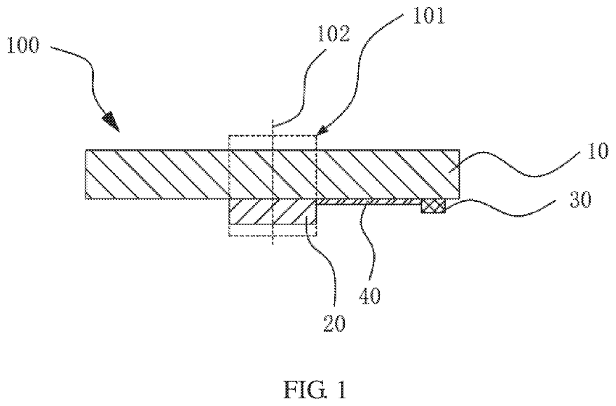

Referring to FIG. 1, the present disclosure of the embodiment provides a flexible display device 100, which includes a display module 10, a heat plate 20, a heat collecting component 30, and a heat conducting tube 40.

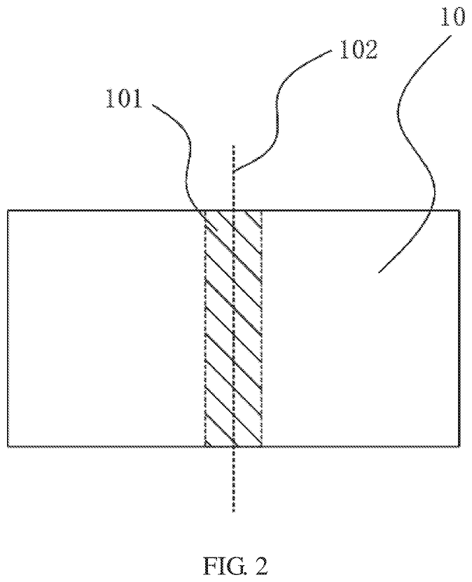

Referring to FIG. 2, a bending area 101 is defined on the display module 10, wherein the bending area 101 is configured to bend, a bending line 102 is defined in the bending area 101, and the display module 10 is bent along the bending line 102.

The heat plate 20 and the heat collecting component 30 are disposed on a side of the display module 10 away from a light emitting surface to avoid affecting the light from the light emitting surface. The heat plate 20 corresponds to the bending area 101, and the heat plate 20 transmits heat to a portion of the display module 10 located in the bending area 101 in an expanded state of the display module 10. Since the flexible display device is able to be bent multiple times, the film material is prone to material stress relaxation and bending fatigue after being bent many times, which causes the surface of the display module 10 in the bending area 101 to warp. Therefore, the heat plate 20 is disposed to correspond to the bending area 101, and the heat on the heat plate 20 is effectively applied to the flattened warped portions. The problem of warping occurring to the surface of the display module 10 is improved by accelerating molecular movement and molecular rearrangement.

Specifically, the heat plate 20 is able to be attached to the back surface of the display module 10 (the surface away from the light emitting surface of the display surface), so that the heat is quickly transferred to the surface of the display module 10.

The heat plate 20 may use graphite or copper foil as the heat equalizing material, and may also be selected from other materials with good heat dissipation properties as the heat equalizing material.

The heat conducting tube 40 is disposed between the heat plate 20 and the heat collecting component 30 and connects the heat plate 20 with the heat collecting component 30. The heat collecting component 30 transfers the collected heat to the heat plate 30 through the heat conducting tube 40. The heat plate 20 transfers heat to the bending area 101 of the display module 10, so that the temperature of the bending area 101 increases. The heat is effectively applied to the bending portion, and the stretching effect of other mechanisms is cooperated, so that the product is restored to a flat level.

In order to make the heat on the heat plate 20 effectively act on the warped portion, a center line of the heat plate 20 and the bending line 102 of the bending area 101 coincide in a thickness direction of the display module 10. In addition, the shape and size of the heat plate 20 may be disposed to be the same as the portion of the display module 10 located in the bending area 101.

The heat conducting tube 40 is disposed on a side of the display module 10 away from the light emitting surface to avoid affecting the display, and is able to attached to the back surface of the display module 10.

The heat conducting tube 40 may be a copper tube or a carbon fiber tube. By using the liquid inside the tube to conduct heat, the surface of the heat conducting tube 40 is able to be covered with a heat-insulating layer to prevent heat from being lost during the conduction process.

The heat collected by the heat collecting component 30 may come from the heat generated by the internal components of the flexible display device 100 during operation, such as the display operation. The driving chip, the battery, the motherboard, and other components in the display module generate heat. The heat is collected, and acts on the warped portion after the produce is flattened. The advantage of providing the heat collecting component 30 is that it is able to dissipate heat from the internal components of the flexible display device 100 without providing additional heat, and prevents the internal components from high-temperature loads due to a long-term operation.

The display module 10 is a flexible organic light emitting diode (OLED) display module, which includes a thin film transistor array substrate, an OLED light-emitting device, a driving chip, and a motherboard.

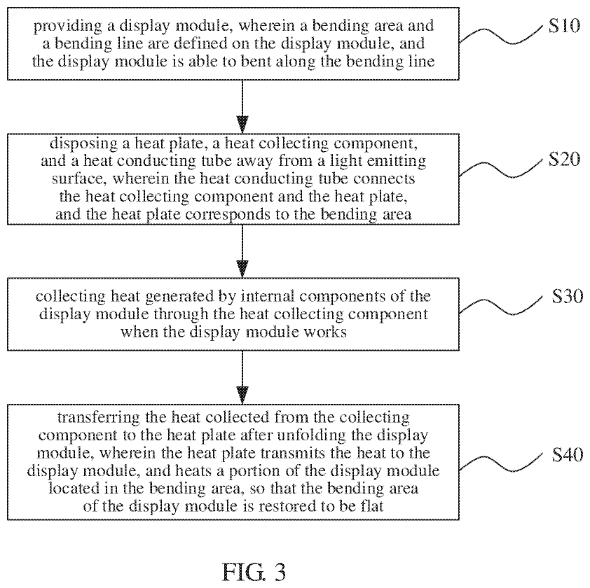

In order to effectively implement the flexible display device in the embodiment of the present disclosure, based on the flexible display device, the embodiment of the present disclosure also provides a method for improving stability of the above-mentioned flexible display device, as shown in FIG. 3, which specifically includes the following steps:

a step S10, providing a display module 10, wherein a bending area 101 and a bending line 102 are defined on the display module, and the display module 10 is able to bent along the bending line 102;

a step S20, disposing a heat plate 20, a heat collecting component 30, and a heat conducting tube 40 away from a side of a light emitting surface of the display module 10, wherein the heat conducting tube 40 connects the heat collecting component 30 with the heat plate 20, and the heat plate 20 corresponds to the bending area 101;

a step S30, collecting heat generated by internal components of the display module 10 through the heat collecting component 30 when the display module 10 works; and

a step S40, transferring the heat collected from the heat collecting component 30 to the heat plate 20 through the heat conducting tube 40 after unfolding the display module 10, wherein the heat plate 20 transmits the heat to the display module 10, and heats a portion of the display module 10 located in the bending area 101, so that the bending area 101 of the display module 10 is restored to be flat.

The heat collecting component 40 is able to collect the heat generated by a driving chip, a battery, and a motherboard of the display module 10.

The heating temperature of the portion of the display module 10 located in the bending area by heating from the heat plate 20 does not exceed 50° C. to avoid damage to the internal components of the display module 10, and a temperature sensor should be provided to monitor the temperature of the bending portion in the bending area 101.

Beneficial effects: the heat plate and the heat collecting component are arranged on the back surface of the display module to collect heat generated during the operation of the display device. When the flexible display device is flattened, the collected heat is applied to the bending portion with warpage to accelerate the molecular movement, so that the warped bending portion is restored to be flat, thereby improving the appearance of the produce and the stability of the product.

In summary, although the present disclosure has been disclosed as above with preferred embodiments, however, the foregoing preferred embodiments are not intended to limit the present disclosure. Those of ordinary skill in the art can make various modifications and decorations without departing from the spirit and scope of this present disclosure. Therefore, the protection scope of this present disclosure is subject to the scope defined by the claims.

What is claimed is:

1. A flexible display device, comprising:
a display module including a bending area, wherein a bending line is defined in the bending area, and the display module is bent along the bending line;
a heat plate disposed on a side of the display module away from a light emitting surface;
a heat collecting component disposed on the side of the display module away from the light emitting surface; and
a heat conducting tube connecting the heat plate with the heat collecting component;
wherein the heat plate corresponds to the bending area, and the heat plate transmits heat to a portion of the display module located in the bending area in an expanded state of the display module; an orthographic projection of the heat plate on the display module is located in the bending area, and the heat plate is attached to a surface of the display module away from the light emitting surface.

2. The flexible display device according to claim 1, wherein a center line of the heat plate and the bending line of the bending area coincide in a thickness direction of the display module.

3. The flexible display device according to claim 1, wherein the heat conducting tube is disposed on the side of the display module away from the light emitting surface.

4. The flexible display device according to claim 3, wherein the display module includes a driving chip, a battery, and a motherboard; the heat collecting component collects heat generated in the driving chip, the battery, and the motherboard.

5. The flexible display device according to claim 1, wherein the heat conducting tube is a copper tube or a carbon fiber tube.

6. A flexible display device, comprising:
a display module including a bending area, wherein a bending line is defined in the bending area, and the display module is bent along the bending line;
a heat plate disposed on a side of the display module away from a light emitting surface;
a heat collecting component disposed on the side of the display module away from the light emitting surface; and
a heat conducting tube connecting the heat plate with the heat collecting component;
wherein the heat plate corresponds to the bending area, and the heat plate transmits heat to a portion of the display module located in the bending area when the display module is in an expanded state.

7. The flexible display device according to claim 6, wherein an orthographic projection of the heat plate on the display module is located in the bending area.

8. The flexible display device according to claim 6, wherein a center line of the heat plate and the bending line of the bending area coincide in a thickness direction of the display module.

9. The flexible display device according to claim 6, wherein the heat plate is attached to a surface of the display module away from the light emitting surface.

10. The flexible display device according to claim 9, wherein the heat conducting tube is disposed on the side of the display module away from the light emitting surface.

11. The flexible display device according to claim 10, wherein the display module includes a driving chip, a battery, and a motherboard; the heat collecting component collects heat generated in the driving chip, the battery, and the motherboard.

12. The flexible display device according to claim 6, wherein the heat conducting tube is a copper tube or a carbon fiber tube.

13. A method for improving stability of a flexible display device, comprising steps of:
a step S10, providing a display module, wherein a bending area and a bending line are defined on the display module, and the display module is able to bent along the bending line;
a step S20, disposing a heat plate, a heat collecting component, and a heat conducting tube away from a light emitting surface, wherein the heat conducting tube connects the heat collecting component with the heat plate, and the heat plate corresponds to the bending area;
a step S30, collecting heat generated by internal components of the display module through the heat collecting component when the display module works; and
a step S40, transferring the heat collected from the heat collecting component to the heat plate after unfolding the display module, wherein the heat plate transmits the heat to the display module, and heats a portion of the display module located in the bending area, so that the bending area of the display module is restored to be flat.

14. The method for improving stability of the flexible display device according to claim 13, wherein in the step S30, the heat collecting component collects the heat generated by a driving chip, a battery, and a motherboard of the display module.

15. The method for improving stability of the flexible display device according to claim 14, wherein in the step S40, the heating temperature of the portion of the display module located in the bending area does not exceed 50° C.

16. The method for improving stability of the flexible display device according to claim 13, wherein the heat conducting tube is a copper tube or a carbon fiber tube.
